(19) United States
(12) Patent Application Publication
(10) Pub. No.: US 2012/0247549 A1
(43) Pub. Date: Oct. 4, 2012

(54) SOLAR CELL AND METHOD FOR MANUFACTURING THE SAME

(75) Inventors: Kyoung Jin Seo, Yongin-si (KR); Meemongkolkiat Vichai, Yongin-si (KR); Byong Gook Jeong, Yongin-si (KR)

(73) Assignees: SAMSUNG SDI CO., LTD., Yongin-si (KR); SAMSUNG ELECTRONICS CO., LTD., Suwon-si (KR)

(21) Appl. No.: 13/294,516

(22) Filed: Nov. 11, 2011

(30) Foreign Application Priority Data
Apr. 1, 2011 (KR) 10-2011-0030240

(51) Int. Cl. H01L 31/0216; H01L 31/18

(52) U.S. Cl. 136/256; 438/98; 438/72; 257/E31.124; 257/E31.127

(57) ABSTRACT

A solar cell includes: a light absorbing layer, a semiconductor layer disposed on a first surface of the light absorbing layer, a first electrode disposed on the semiconductor layer in a first direction of the semiconductor layer, a first passivation layer disposed on a second surface of the light absorbing layer, a second passivation layer disposed on the first passivation layer in a second direction opposite to the first direction of the semiconductor layer, a contact hole disposed in the first passivation layer and the second passivation layer and exposing a portion of the light absorbing layer, and a second electrode disposed on the second passivation layer in the second direction of the second passivation layer and connected with the light absorbing layer through the contact hole. The second passivation layer is made of a compound containing carbon.

### CROSS-REFERENCE TO RELATED APPLICATION

This application claims priority to Korean Patent Application No. 10-2011-0030240 filed on Apr. 1, 2011, the entire disclosure of which is hereby incorporated by reference herein in its entirety.

### BACKGROUND OF THE INVENTION

(a) Technical Field of the Invention

The present disclosure relates to a solar cell and a method for manufacturing the same.

(b) Description of the Related Art

A solar cell converts solar energy into electrical energy. The solar cell, which may be principally a diode configured by PN junction, may be classified into various types according to the material used as a light absorbing layer.

The solar cell using silicon as the light absorbing layer may be classified into, for example, a crystalline wafer type solar cell and a thin film type (crystalline and amorphous) solar cell.

Since the crystalline wafer type solar cell has beneficial junction characteristics of a P layer and an N layer, the output current and the fill factor thereof may be increased.

Meanwhile, in the crystalline wafer type solar cell, a passivation layer is formed to protect a solar cell after PN junction is formed and the passivation layer should maintain stability to heat and minimize a negative charge drop of an oxide film.

There is still a need in the art to provide a solar cell having a passivation layer with increased heat stability and increased electrical characterisitcs and for a method for manufacturing the same.

### SUMMARY OF THE INVENTION

Exemplary embodiments of the present invention may provide a solar cell and a method for manufacturing the same which increase the efficiency of the solar cell by providing a passivation layer having increased stability to heat and increased electrical characteristics.

An exemplary embodiment of the present invention provides a solar cell, including: a light absorbing layer, a semiconductor layer disposed on a first surface of the light absorbing layer, a first electrode disposed on the semiconductor layer in a first direction of the semiconductor layer, a first passivation layer disposed on a second surface of the light absorbing layer, a second passivation layer disposed on the first passivation layer in a second direction opposite to the first direction of the semiconductor layer, a contact hole disposed in the first passivation layer and the second passivation layer and exposing a portion of the light absorbing layer, and a second electrode disposed on the second passivation layer in the second direction of the second passivation layer and connected with the light absorbing layer through the contact hole. The second passivation layer is made of a compound containing carbon.

The second passivation layer may be made of a silicon carbon nitride compound.

The content of carbon in the second passivation layer may be in the range of about 6 atomic percent (at %) to about 12 at %.

The second passivation layer may be made of any one of silicon carbide and diamond-like carbon (DLC).

The first passivation layer may be made of any one of aluminum oxide and aluminum nitride.

The semiconductor layer may be doped with N-type dopants.

An exemplary embodiment of the present invention provides a method for manufacturing a solar cell, the method including: forming a semiconductor layer on a first surface of a light absorbing layer, forming a first passivation layer and a second passivation layer on a second surface of the light absorbing layer in sequence, forming a contact hole exposing a portion of the light absorbing layer by etching the first passivation layer and the second passivation layer, applying a first electrode onto the semiconductor layer in a first direction of the semiconductor layer, applying a second electrode onto the second passivation layer in a second direction opposite to the first direction of the semiconductor layer, and firing the first electrode and the second electrode. The second passivation layer is made of a compound containing carbon.

An exemplary embodiment of the present invention provides a method for manufacturing a solar cell, the method including: forming a semiconductor layer on a first surface of a light absorbing layer, forming an anti-reflective layer on the semiconductor layer in a first direction of the semiconductor layer, forming a first passivation layer composed of an oxide having negative charges on a second surface of the light absorbing layer, forming a second passivation layer composed of a silicon carbon nitride compound on the first passivation layer in a second direction opposite to the first direction of the semiconductor layer and forming a contact hole in the first passivation layer and the second passivation layer exposing a portion of the light absorbing layer and forming a first electrode by applying a low resistance metal onto the anti-reflective layer in the first direction of the anti-reflective layer. The method further includes forming a second electrode by applying a applying a metal onto the second passivation layer in the second direction of the second passivation layer and forming an impurity layer in the portion of the light absorbing layer exposed by the contact hole.

According to exemplary embodiments of the present invention, a first passivation layer can be prevented from being deteriorated even though a thermal process such as firing is performed by forming a second passivation layer composed of a silicon carbon nitride compound.

Further, since the quantity of negative charges of the second passivation layer increases, positive charges of the light absorbing layer readily move to a second electrode and a large quantity of positive charges move, and as a result, the efficiency of a solar cell can be increased.

### BRIEF DESCRIPTION OF THE DRAWINGS

FIG. 1 is a cross-sectional view of a solar cell according to an exemplary embodiment of the present invention.

FIGS. 2 to 4 are diagram sequentially showing a method for manufacturing a solar cell according to an exemplary embodiment of the present invention.

FIG. 5 is a graph comparing charge characteristics of a first passivation layer and a second passivation layer in a solar cell according to exemplary embodiments and charge characteristics of a first passivation layer and a second passivation layer in a solar cell according to a comparative example with each other.

### DETAILED DESCRIPTION OF EXEMPLARY EMBODIMENTS OF THE PRESENT INVENTION

Exemplary embodiments of the present invention will be described more fully hereinafter with reference to the accompanying drawings. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present.

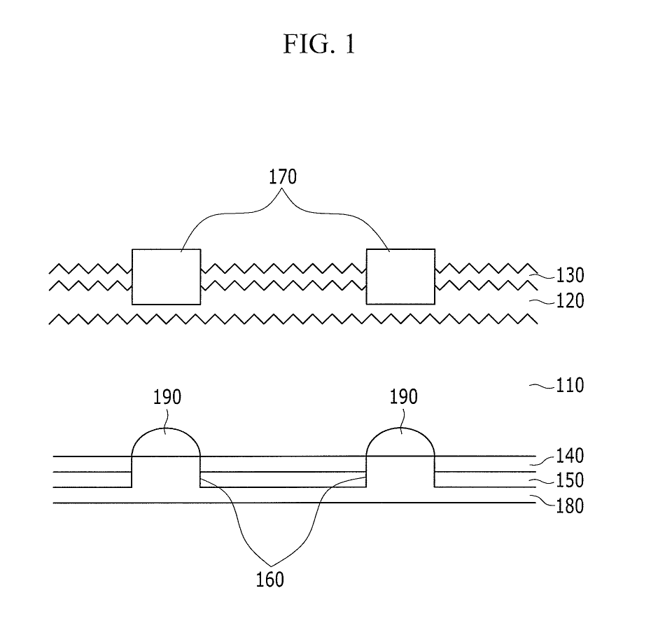

FIG. 1 is a cross-sectional view of a solar cell according to an exemplary embodiment of the present invention.

As shown in FIG. 1, the solar cell according to an exemplary embodiment of the present invention includes, for example, a light absorbing layer 110, a semiconductor layer 120, an anti-reflective layer 130, and a first electrode 170 sequentially positioned on a first surface of the light absorbing layer 110, and a first passivation layer 140, a second passivation layer 150, and a second electrode 180 sequentially positioned on a second surface of the light absorbing layer 110. Further, the light absorbing layer 110 includes an impurity layer 190 positioned at a junction portion with the second electrode 180.

A crystalline silicon wafer is used as the light absorbing layer 110 and serves as a p-type semiconductor actually absorbing light. The first surface of the light absorbing layer 110 is textured to reduce reflection of incident light.

For example, the semiconductor layer 120 is composed of amorphous silicon and is doped with N-type dopants such as phosphor (P), arsenic (As), and antimony (Sb). However, it is noted that other N-type dopants such as, for example, nitrogen (N) may also be used for doping the semiconductor layer 120 as is understood by one skilled in the art.

Further, for example, as the light absorbing layer 110, an N-type silicon wafer may be used. In this case, for example, in the semiconductor layer 120 composed of amorphous silicon is doped with P-type dopants such as boron (B) and aluminum (Al). It is noted that other P-type dopants such as, for example, gallium (ga) may also be used for doping the semiconductor layer 120 as is understood by one skilled in the art.

Solar light absorbed by PN junction of the light absorbing layer 110 and the semiconductor layer 120 generates current.

The anti-reflective layer 130 is made of, for example, silicon nitride (SiNx) and serves as the anti-reflective layer preventing incident light from being reflected.

The first electrode 170 is made of low-resistance metal such as, for example, silver (Ag) and designed by a grid pattern to reduce a shadowing loss and sheet resistance. The first electrode 170 contacts the semiconductor layer 120.

Further, a buffer layer preventing recombination of electrons may be positioned between the light absorbing layer 110 and the semiconductor layer 120. Alternatively, the buffer layer may be omitted.

The first passivation layer 140 is formed by an oxide film such as, for example, aluminum oxide (Al₂O₃) or aluminum nitride oxide (AlON) having negative charges. The first passivation layer 140 reflects minority carriers generated by light energy as fixed negative charges again and sends the reflected carriers to the first electrode 170 to increase short-circuit current, thereby increasing the efficiency of the solar cell.

The second passivation layer 150 is made of, for example, silicon carbon nitride (SixCyNz and x, y, and z are 1 or more). The second passivation layer 150 prevents a film characteristic of the first passivation layer 140 from being deteriorated by a time and an environmental influence. Further, since the ratio of hydrogen (H) in the second passivation layer 150 decreases by carbon (C) contained in the second passivation layer 150, the quantity of negative charges of the second passivation layer 150 increases. As a result, positive charges of the light absorbing layer 110 readily moves to the second electrode 180 to be described below and a large quantity of positive charges move, thereby increasing the efficiency of the solar battery.

Herein, the content of carbon in the second passivation layer 150 is in the range of for example, about 6 atomic percent (at %) to about 12 at %. The second passivation layer 150 including a silicon carbon nitride compound containing carbon in the above mentioned amount is stable to heat, is readily processed, and has a long lifespan.

Further, the second passivation layer 150 may be made of, for example, silicon carbide (SiC), diamond-like carbon (DLC), silicon dioxide (SiO₂), or aluminum nitride (AlN).

A contact hole 160 exposing the light absorbing layer 110 is formed on the first passivation layer 140 and the second passivation layer 150.

The second electrode 180 is made of a metal including, for example, aluminum (Al) and is connected with the light absorbing layer 110 through the contact hole 160.

The impurity layer 190 is positioned in a part of the light absorbing layer 110 which is exposed by the contact hole 160. The impurity layer 190 is formed by doping the light absorbing layer 110 with aluminum of the second electrode 180 and prevents recombination of electrons and has a back surface field (BSF) effect to increase the collection efficiency of generated carriers.

Next, a method for manufacturing the solar cell according to an exemplary embodiment of the present invention will be described in detail with reference to FIGS. 2 to 4 and 1.

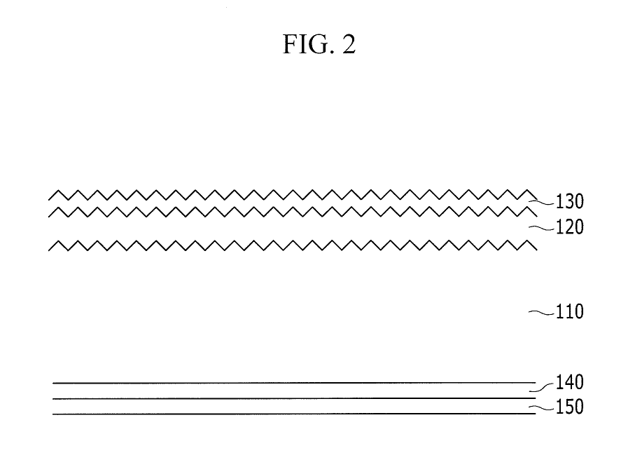

FIGS. 2 to 4 are diagram sequentially showing a method for manufacturing the solar cell according to an exemplary embodiment of the present invention.

As shown in FIG. 2, the semiconductor layer 120 is formed on the first surface of the light absorbing layer 110 and the anti-reflective layer 130 made of, for example, silicon nitride (SiNx) is formed on the semiconductor layer in a first direction of the semiconductor layer 120. The first surface of the light absorbing layer 110 is textured to reduce light reflection and the semiconductor layer 120 is doped with N-type dopants such as, for example, phosphor (P), arsenic (As), and antimony (Sb). It is noted that other N-type dopants such as, for example, nitrogen (N) may also be used for doping the semiconductor layer 120 as is understood by one skilled in the art.

For example, the first passivation layer 140 formed by an oxide film such as aluminum oxide or aluminum nitride oxide having negative charges is formed on the second surface of the light absorbing layer 110 and the second passivation layer 150 made of silicon carbon nitride is formed on the first passivation layer 140 in a second direction opposite to the first direction of the semiconductor layer 120. However, it is noted that exemplary embodiments of the present invention are not limited to the above-mentioned positioning of the semiconductor layer 120, the light absorbing layer 110, the first passivation layer 140 and the second passivation layer 150 depicted in FIGS. 1-4 but rather alternatively, the first passivation layer 140 and the second passivation layer 150 may instead be sequentially formed on the first surface of the light absorbing layer 110 and the semiconductor layer 120 and the anti-reflective layer 130 may instead be sequentially formed on the second surface of the light absorbing layer 110 which is opposite to the first surface of the light absorbing layer 110 as is understood by one skilled in the art.

The second passivation layer 150 is formed by, for example, injecting carbon (C) and ammonia (NH₃) into silicon (Si). In this case, the content of carbon may be in the range of, for example, about 6 at % to about 12 at %. The second passivation layer 150 including a silicon carbon nitride compound containing carbon in the above mentioned amount is stable to heat, is readily processed, and has a long lifespan.

Further, the second passivation layer 150 may be made of, for example, silicon carbide (SiC), diamond-like carbon (DLC), silicon dioxide (SiO₂), or aluminum nitride (AlN).

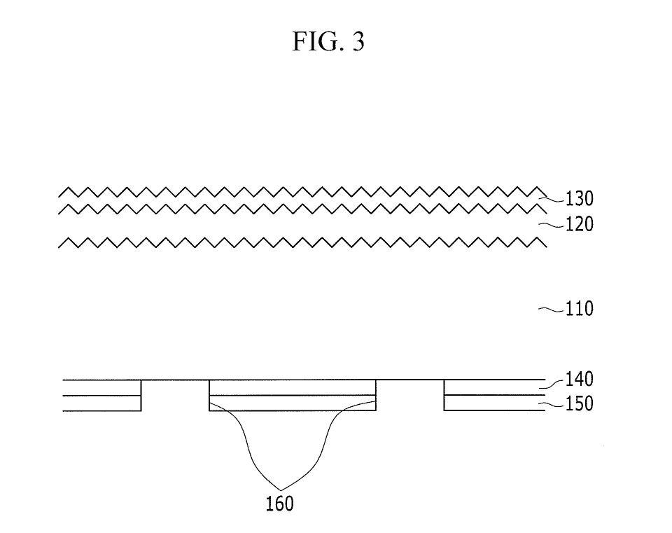

Subsequently, as shown in FIG. 3, the contact hole 160 exposing the light absorbing layer 110 is formed by etching parts of the first passivation layer 140 and the second passivation layer 150.

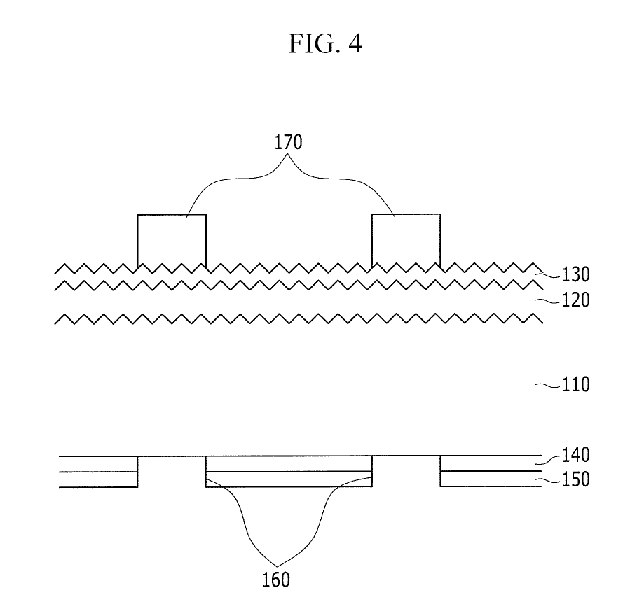

Subsequently, as shown in FIG. 4, the first electrode 170 is formed by applying a low-resistance metal such as, for example, silver onto the anti-reflective layer 130 in the first direction of the anti-reflective layer 130. Referring back to FIG. 1. the second electrode 180 is formed by applying a metal including, for example, aluminum onto the second passivation layer 150 in the second direction of the second passivation layer 150. Herein, the second electrode 180 is connected to the light absorbing layer 110 through the contact hole 160.

Subsequently, as shown in FIG. 1, the first electrode 170 and the semiconductor layer 120 contact each other by firing the first electrode 170 and the second electrode 180 to form the impurity layer 190.

Firing is performed at about 780° C. or higher in a short time. In this case, aluminum configuring the second electrode 180 is diffused to the light absorbing layer 110 through the contact hole 160 to form the impurity layer 190.

Further, the first electrode 170 applied onto the anti-reflective layer 130 contacts the semiconductor layer 120.

As such, the second passivation layer 150 is made of, for example, silicon carbon nitride, thereby preventing the first passivation layer 140 from being deteriorated even by performing a thermal process such as firing, and preventing the resultant bubbles from being generated.

Further, since the quantity of positive charges of the second passivation layer 150 increases, the positive charges of the light absorbing layer 110 readily move to the second electrode 180 and since a large quantity of positive charges move, the efficiency of the solar cell is increased.

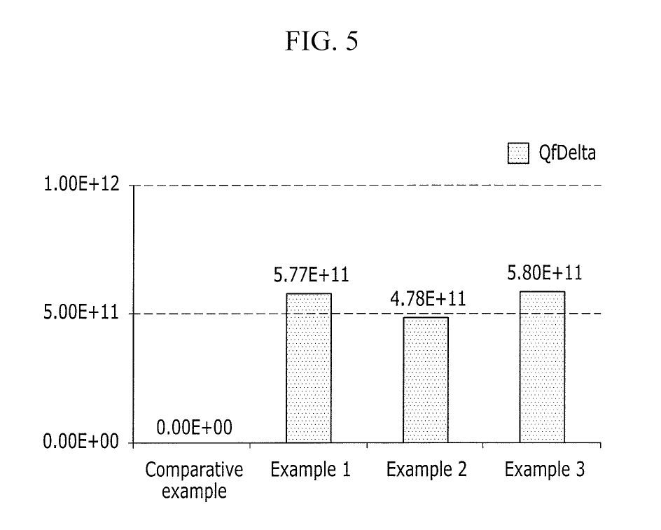

Hereinafter, a characteristic of the solar cell according to the solar cell according to an exemplary embodiment of the present invention and a characteristic of a solar cell according to a comparative example will be described with reference to FIG. 5.

In a solar cell according to an exemplary embodiment, the first passivation layer is made of, for example, aluminum oxide (Al₂O₃) and the second passivation layer is made of, for example, silicon carbon nitride. In this case, the content of carbon in the second passivation layer is, for example, about 12 at %.

In a solar cell according to an exemplary embodiment, the first passivation layer is made of, for example, aluminum oxide (Al₂O₃) and the second passivation layer is made of, for example, silicon carbon nitride. In this case, the content of carbon in the second passivation layer is, for example, about 10 at %.

In a solar cell according to an exemplary embodiment, the first passivation layer is made of, for example, aluminum oxide (Al₂O₃) and the second passivation layer is made of, for example, silicon carbon nitride. In this case, the content of carbon in the second passivation layer is, for example, about 6 at %.

In a solar cell according to a comparative example, the first passivation layer is made of aluminum oxide (Al₂O₃) and the second passivation layer is made of silicon nitride.

FIG. 5 is a graph comparing charge characteristics of a first passivation layer and a second passivation layer in a solar cell according to exemplary embodiments and charge characteristics of a first passivation layer and a second passivation layer in a solar cell according to a comparative example with each other.

FIG. 5 shows the quantity of negative charges of the first passivation layer and the second passivation layer according to exemplary embodiments when the quantity of negative charges of the first passivation layer and the second passivation layer according to the comparative example is 0.

As shown in FIG. 5, when the quantity of negative charges of the first passivation layer and the second passivation layer according to the comparative example is 0, the quantity of negative charges of the first passivation layer and the second passivation layer according to an exemplary embodiment was about 5.77E+11, the quantity of negative charges of the first passivation layer and the second passivation layer according to an exemplary embodiment was about 4.78E+11, and the quantity of negative charges of the first passivation layer and the second passivation layer according to an exemplary embodiment was about 5.08E+11.

As the quantity of negative charges of the first passivation layer and the second passivation layer increases, the positive charges of the light absorbing layer move to the second electrode more readily and the movement quantity of the positive charges of the light absorbing layer increases, and as a result, the efficiency of the solar cell can be increased.

That is, it can be seen that since the quantity of negative charges of the first passivation layer and the second passivation layer according to exemplary embodiments is larger than that of the first passivation layer and the second passivation layer according to the comparative example, the efficiency of the solar cell according to exemplary embodiments is increased greater than the efficiency of the solar cell according to the comparative example.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A solar cell, comprising:
a light absorbing layer;
a semiconductor layer disposed on a first surface of the light absorbing layer;
a first electrode disposed on the semiconductor layer in a first direction of the semiconductor layer;
a first passivation layer disposed on a second surface of the light absorbing layer;
a second passivation layer disposed on the first passivation layer in a second direction opposite to the first direction of the semiconductor layer;
a contact hole disposed in the first passivation layer and the second passivation layer and exposing a portion of the light absorbing layer; and
a second electrode disposed on the second passivation layer in the second direction of the second passivation layer and connected with the light absorbing layer through the contact hole,
wherein the second passivation layer is made of a compound containing carbon.

2. The solar cell of claim 1, wherein:
the compound of the second passivation layer is silicon carbon nitride.

3. The solar cell of claim 2, wherein:
a content of the carbon in the second passivation layer is in a range of about 6 atomic percent (at %) to about 12 at %.

4. The solar cell of claim 1, wherein:
the second passivation layer is made of one of silicon carbide and diamond-like carbon (DLC).

5. The solar cell of claim 1, wherein:
the first passivation layer is made of one of aluminum oxide and aluminum nitride.

6. The solar cell of claim 1, wherein:
the semiconductor layer is doped with N-type dopants.

7. The solar cell of claim 1, further comprising an impurity layer disposed in the portion of the light absorbing layer exposed by the contact hole.

8. The solar cell of claim 7, further comprising an anti-reflective layer formed on the semiconductor layer in the first direction of the semiconductor layer and wherein the first electrode is formed directly on the anti-reflective layer.

9. The solar cell of claim 2, wherein the silicon carbon nitride compound of the second passivation layer is represented by the chemical formula (SixCyNz, and wherein each of x, y, and z are no less than 1).

10. A method for manufacturing a solar cell, the method comprising:
forming a semiconductor layer on a first surface of a light absorbing layer;
forming a first passivation layer and a second passivation layer on a second surface of the light absorbing layer in sequence;
forming a contact hole exposing portion of the light absorbing layer by etching the first passivation layer and the second passivation layer;
applying a first electrode onto the semiconductor layer in a first direction of the semiconductor layer;
applying a second electrode onto the second passivation layer in a second direction opposite to the first direction of the semiconductor layer; and
firing the first electrode and the second electrode,
wherein the second passivation layer is made of a compound containing carbon.

11. The method of claim 10, wherein:
the compound of the second passivation layer is made of silicon carbon nitride.

12. The method of claim 11, wherein:
a content of the carbon in the second passivation layer is in a range of about 6 atomic percent (at %) to about 12 at %.

13. The method of claim 10, wherein:
the second passivation layer is made of one of silicon carbide and diamond-like carbon (DLC).

14. The method of claim 10, wherein:
the first passivation layer is made of one of aluminum oxide and aluminum nitride.

15. The method of claim 10, wherein:
the forming of the semiconductor layer includes doping the semiconductor layer with N-type dopants.

16. A method for manufacturing a solar cell, the method comprising:
forming a semiconductor layer on a first surface of a light absorbing layer;
forming an anti-reflective layer on the semiconductor layer in a first direction of the semiconductor layer;
forming a first passivation layer composed of an oxide having negative charges on a second surface of the light absorbing layer;
forming a second passivation layer composed of a silicon carbon nitride compound on the first passivation layer in a second direction opposite to the first direction of the semiconductor layer;
forming a contact hole in the first passivation layer and the second passivation layer exposing a portion of the light absorbing layer;
forming a first electrode by applying a low resistance metal onto the anti-reflective layer in the first direction of the anti-reflective layer;
forming a second electrode by applying a metal onto the second passivation layer in the second direction of the second passivation layer; and
forming an impurity layer in the portion of the light absorbing layer exposed by the contact hole.

17. The method of claim 16, wherein the first surface of the light absorbing layer is textured to reduce light reflection and the semiconductor layer is doped with one of phosphor (P), arsenic (As), and antimony (Sb).

18. The method of claim 16, wherein the second passivation layer is formed by injecting carbon and ammonia into silicon, wherein a content of the carbon in the second passivation layer is about 6 atomic percent (at) % to about 12 at % and wherein the first passivation layer is formed of one of an aluminum oxide having negative charges or aluminum nitride oxide film having negative charges.

19. The method of claim 16, wherein the second electrode is made of aluminum and is connected with the light absorbing layer through the contact hole.

20. The method of claim 16, wherein the first electrode and the second electrode are fired such that the first electrode and the semiconductor layer contact each other to thereby form the impurity layer.
